(19) United States
(12) Patent Application Publication
(10) Pub. No.: US 2014/0170338 A1
(43) Pub. Date: Jun. 19, 2014

(54) pvd chamber and process for over-coating layer to improve emissivity for low emissivity coating

(71) Applicant: INTERMOLECULAR INC., San Jose, CA (US)

(72) Inventors: Guowen Ding, San Jose, CA (US); Brent Boyce, Novi, MI (US); Mohd Fadzli Anwar Hassan, San Francisco, CA (US); Minh Huu Le, San Jose, CA (US); Zhi-Wen Wen Sun, Sunnyvale, CA (US); Yu Wang, San Jose, CA (US)

(73) Assignee: Intermolecular Inc., San Jose, CA (US)

(21) Appl. No.: 13/714,797

(22) Filed: Dec. 14, 2012

(51) Int. Cl. C23C 14/34

(52) U.S. Cl. CPC C23C 14/3492
USPC 427/595; 118/620; 204/192.12; 204/192.15; 204/298.11; 204/298.23

(57) ABSTRACT

A method for making low emissivity panels, including control the ion characteristics, such as ion energy, ion density and ion to neutral ratio, in a sputter deposition process of a layer deposited on a thin conductive silver layer. The ion control can prevent or minimize degrading the quality of the conductive silver layer, which can lead to better transmittance in visible regime, block more heat transfer from the low emissivity panels, and potentially can reduce the requirements for other layers, so that the overall performance, such as durability, could be improved.

### FIELD OF THE INVENTION

The present invention relates generally to films providing high transmittance and low emissivity, and more particularly to such films deposited on transparent substrates.

### BACKGROUND OF THE INVENTION

Sunlight control glasses are commonly used in applications such as building glass windows and vehicle windows, typically offering high visible transmission and low emissivity. High visible transmission can allow more sunlight to pass through the glass windows, thus being desirable in many window applications. Low emissivity can block infrared (IR) radiation to reduce undesirable interior heating.

In low emissivity glasses, IR radiation is mostly reflected with minimum absorption and emission, thus reducing the heat transferring to and from the low emissivity surface. Low emissivity, or low-e, panels are often formed by depositing a reflective layer (e.g., silver) onto a substrate, such as glass. The overall quality of the reflective layer, such as with respect to texturing and crystallographic orientation, is important for achieving the desired performance, such as high visible light transmission and low emissivity (i.e., high heat reflection). In order to provide adhesion, as well as protection, several other layers are typically formed both under and over the reflective layer. The various layers typically include dielectric layers, such as silicon nitride, tin oxide, and zinc oxide, to provide a barrier between the stack and both the substrate and the environment, as well as to act as optical fillers and function as anti-reflective coating layers to improve the optical characteristics of the panel.

One known method to achieve low emissivity is to form a relatively thick silver layer. However, as the thickness of the silver layer increases, the visible light transmission of the reflective layer is reduced, as is manufacturing throughput, while overall manufacturing costs are increased. Therefore, is it desirable to form the silver layer as thin as possible, while still providing emissivity that is suitable for low-e applications.

### SUMMARY OF THE DISCLOSURE

In some embodiments, the present invention discloses methods and apparatuses for making coated articles which comprise a low resistivity thin infrared reflective layer comprising a conductive material such as silver. By restricting the ion density or ion energy during the sputter deposition process of the coated layers on the conductive layer, degradation of the resistivity of the conductive layer can be avoided, resulting in low emissivity of the coated article for a same light transmittance.

In some embodiments, the present invention discloses a sputter deposition for a barrier layer or an oxide layer disposed over a conductive layer, wherein the sputter deposition uses low ion energy or low ion density. For example, the low ion energy of the barrier layer deposition process can reduce reaction for the conductive underlayer, preventing resistivity and emissivity degradation. The low ion energy of the oxide layer deposition process can reduce oxidation of the conductive underlayer, preventing resistivity and emissivity degradation.

In some embodiments, the present invention discloses a sputter deposition system having controllable ion energy or ion density, for example, for depositing a barrier layer or an oxide layer on a conductive layer for low emissivity panels. For example, the ion energy control can be achieved by increasing the distance between the sputter target and the substrate, which can lower the electric field between the target and the substrate, and consequently the energy of the ions. Increasing the distance can also lower the ion density, since this can effectively increase the sputtering area on the substrate for a same number of reactive ions. The ion density control can be achieved by reducing the ion density in the sputter chamber, including reducing the ratio of ion species to neutral species. For example, a screen shield can be disposed between the sputter target and the substrate, blocking more ion species than neutral species, thus effectively increasing the ion to neutral ratio.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1A illustrates an exemplary thin film coating according to some embodiments of the present invention.

FIG. 1B illustrates a low emissivity transparent panel 105 according to some embodiments of the present invention.

FIG. 2 illustrates an example of the effect of the deposition conditions of a barrier layer on a silver layer according to some embodiments of the present invention.

FIG. 3 illustrates a normal throw physical vapor deposition (PVD) system according to some embodiments of the present invention.

FIG. 4 illustrates a long throw physical vapor deposition (PVD) system according to some embodiments of the present invention.

FIGS. 5A-5B illustrate deposition systems having an ion control system according to some embodiments of the present invention.

FIG. 6 illustrates an exemplary in-line deposition system according to some embodiments of the present invention.

FIG. 7 illustrates a flow chart for sputtering coated layers according to some embodiments of the present invention.

FIG. 8 illustrates a flow chart for sputtering layers according to some embodiments of the present invention.

FIG. 9 illustrates another flow chart for sputtering coated layers according to some embodiments of the present invention.

FIGS. 10A-10B illustrate examples of sheet resistance and emissivity data for low emissivity stacks according to some embodiments of the present invention.

### DETAILED DESCRIPTION OF THE PREFERRED EMBODIMENTS

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

In some embodiments, the present invention discloses methods and apparatuses for making coated panels. The coated panels can include coated layers formed thereon, such as a low resistivity thin infrared reflective layer having a conductive material such as silver.

In some embodiments, the present invention discloses methods and apparatuses for making low emissivity coated panels, which include sputter depositing a barrier layer or an oxide layer on a conductive layer such as silver in such conditions so that the resistivity of silver, and consequently the emissivity of the coated panels, is optimum. For example, the low resistive silver layer or the low emissivity panel can be achieved by low ion energy or ion density during subsequent sputter deposition processes, which can reduce the degradation of the silver conductive layer, for example, by reducing the reaction of the silver conductive layer with the oxygen ions.

In some embodiments, the present invention discloses sputter depositing a barrier layer or an oxide layer on a conductive layer, wherein the sputter deposition process uses low ion energy or low ion density. By restricting the ion energy or ion density during the sputter deposition process of the coated layers on the conductive layer, degradation of the resistivity of the conductive layer can be avoided, resulting in low emissivity of the coated article for a same light transmittance. For example, the low ion energy of the barrier layer deposition process can reduce reaction for the conductive underlayer, preventing resistivity and emissivity degradation. The low ion energy of the oxide layer deposition process can reduce oxidation of the conductive underlayer, preventing resistivity and emissivity degradation.

In some embodiments, the present invention discloses methods and apparatuses for making low emissivity panels which include a low resistivity thin infrared reflective layer including a conductive material such as silver, gold, or copper. The thin silver layer can be thinner than 10 nm, such as 7 or 8 nm. The silver layer can have low roughness, and is preferably deposited on a seed layer also having low roughness. The low emissivity panels can have improved overall quality of the infrared reflective layer with respect to conductivity, physical roughness and thickness. For example, the methods allow for improved conductivity of the reflective layer such that the thickness of the reflective layer may be reduced while still providing desirably low emissivity.

In general, the reflective layer preferably has low sheet resistance, since low sheet resistance is related to low emissivity. In addition, the reflective layer is preferably thin to provide high visible light transmission. Thus in some embodiments, the present invention discloses methods and apparatuses to deposit a thin and highly conductive reflective layer, providing a coated layer with high visible transmittance and low infrared emissivity. The methods can also maximize volume production, throughput, and efficiency of the manufacturing process used to form low emissivity panels.

In some embodiments, the present invention discloses an improved coated transparent panel, such as a coated glass, that has acceptable visible light transmission and IR reflection. The present invention also discloses methods of producing the improved, coated, transparent panels, which comprise specific layers in a coating stack.

The coated transparent panels can comprise a glass substrate or any other transparent substrates, such as substrates made of organic polymers. The coated transparent panels can be used in window applications such as vehicle and building windows, skylights, or glass doors, either in monolithic glazings or multiple glazings with or without a plastic interlayer or a gas-filled sealed interspace.

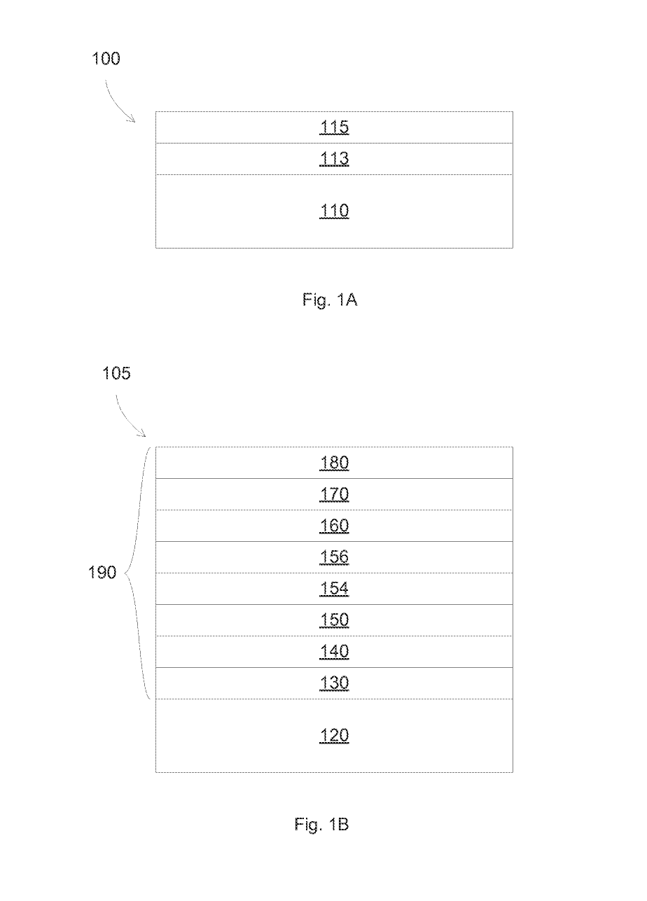

FIG. 1A illustrates an exemplary thin film coating according to some embodiments of the present invention. A layer 115 is disposed on an infrared reflective layer 113, such as a silver layer, which is disposed on a substrate 110 to form a coated transparent panel 100, which has high visible light transmission, and low IR emission.

The layer 115 can be sputtered deposited using different processes and equipment, for example, the targets can be sputtered under direct current (DC), pulsed DC, alternate current (AC), radio frequency (RF) or any other suitable conditions. In some embodiments, the present invention discloses a physical vapor deposition method for depositing a layer 115 with minimum affect on the infrared reflective layer 113. In some embodiments, the method includes controlling the ion energy or the ion density of the sputtered particles between the target and the substrate 110. For example, a long distance between the target and the substrate, a ground screen, or a bias screen can be used to restrict the energy or ion to neutral ratio of the sputtered particles that can reach the substrate. The processing chamber can include a gas mixture introduced to a plasma ambient to sputter material from one or more targets disposed in the processing chamber. The sputtering process can further include other components such as magnets for confining the plasma, and utilize different process conditions such as DC, AC, RF, or pulsed sputtering.

In some embodiments, the layer 115 can include an oxide layer, a seed layer, a conductive layer, a barrier layer, an antireflective layer, or a protective layer. In some embodiments, the present invention discloses forming a layer 115 on a high transmittance, low emissivity coated article having a substrate and a smooth metallic reflective film including one of silver, gold, or copper.

In some embodiments, the present invention discloses a coating stack, comprising multiple layers for different functional purposes. For example, the coating stack can comprise a seed layer to facilitate the deposition of the reflective layer, an oxygen diffusion layer disposed on the reflective layer to prevent oxidation of the reflective layer, a protective layer disposed on the substrate to prevent physical or chemical abrasion, or an antireflective layer to reduce visible light reflection. The coating stack can comprise multiple layers of reflective layers to improve IR emissivity.

FIG. 1B illustrates a low emissivity transparent panel 105 according to some embodiments of the present invention. The low emissivity transparent panel can comprise a glass substrate 120 and a low emissivity (low-e) stack 190 formed over the glass substrate 120. The glass substrate 120 in one embodiment is made of a glass, such as borosilicate glass, and has a thickness of, for example, between 1 and 10 millimeters (mm). The substrate 120 may be square or rectangular and about 0.5-2 meters (m) across. In some embodiments, the substrate 120 may be made of, for example, plastic or polycarbonate.

The low-e stack 190 includes a lower protective layer 130, a lower oxide layer 140, a seed layer 150, a reflective layer 154, a barrier layer 156, an upper oxide 160, an optical filler layer 170, and an upper protective layer 180. Some layers can be optional, and other layers can be added, such as interface layers or adhesion layers. Exemplary details as to the functionality provided by each of the layers 130-180 are provided below.

The various layers in the low-e stack 190 may be formed sequentially (i.e., from bottom to top) on the glass substrate 120 using a physical vapor deposition (PVD) and/or reactive (or plasma enhanced) sputtering processing tool. In some embodiments, the low-e stack 190 is formed over the entire glass substrate 120. However, in other embodiments, the low-e stack 190 may only be formed on isolated portions of the glass substrate 120.

The lower protective layer 130 is formed on the upper surface of the glass substrate 120. The lower protective layer 130 can comprise silicon nitride, silicon oxynitride, or other nitride material such as SiZrN, for example, to protect the other layers in the stack 190 from diffusion from the substrate 120 or to improve the haze reduction properties. In some embodiments, the lower protective layer 130 is made of silicon nitride and has a thickness of, for example, between about 10 nm to 50 nm, such as 25 nm.

The lower oxide layer 140 is formed on the lower protective layer 130 and over the glass substrate 120. The lower oxide layer is preferably a metal or metal alloy oxide layer and can serve as an antireflective layer. The lower metal oxide layer 140 may enhance the crystallinity of the reflective layer 154, for example, by enhancing the crystallinity of a seed layer for the reflective layer, as is described in greater detail below.

The layer 150 can be used to provide a seed layer for the IR reflective film, for example, a zinc oxide layer deposited before the deposition of a silver reflective layer can provide a silver layer with lower resistivity, which can improve its reflective characteristics. The seed layer can comprise a metal such as titanium, zirconium, and/or hafnium, or a metal alloy such as zinc oxide, nickel oxide, nickel chrome oxide, nickel alloy oxides, chrome oxides, or chrome alloy oxides.

In some embodiments, the seed layer 150 can be made of a metal, such as titanium, zirconium, and/or hafnium, and has a thickness of, for example, 50 Å or less. Generally, seed layers are relatively thin layers of materials formed on a surface (e.g., a substrate) to promote a particular characteristic of a subsequent layer formed over the surface (e.g., on the seed layer). For example, seed layers may be used to affect the crystalline structure (or crystallographic orientation) of the subsequent layer, which is sometimes referred to as “templating.” More particularly, the interaction of the material of the subsequent layer with the crystalline structure of the seed layer causes the crystalline structure of the subsequent layer to be formed in a particular orientation.

For example, a metal seed layer is used to promote growth of the reflective layer in a particular crystallographic orientation. In some embodiments, the metal seed layer is a material with a hexagonal crystal structure and is formed with a (002) crystallographic orientation which promotes growth of the reflective layer in the (111) orientation when the reflective layer has a face centered cubic crystal structure (e.g., silver), which is preferable for low-e panel applications.

In some embodiments, the crystallographic orientation can be characterized by X-ray diffraction (XRD) technique, which is based on observing the scattered intensity of an X-ray beam hitting the layer, e.g., silver layer or seed layer, as a function of the X-ray characteristics, such as the incident and scattered angles. For example, zinc oxide seed layer can show a pronounced (002) peak and higher orders in a θ-2θ diffraction pattern. This suggests that zinc oxide crystallites with the respective planes oriented parallel to the substrate surface are present.

In some embodiments, the terms “silver layer having (111) crystallographic orientation”, or “zinc oxide seed layer having (002) crystallographic orientation” include a meaning that there is a (111) crystallographic orientation for the silver layer or a (002) crystallographic orientation for the zinc oxide seed layer, respectively. The crystallographic orientation can be determined, for example, by observing pronounced crystallography peaks in an XRD characterization.

In some embodiments, the seed layer 150 can be continuous and covers the entire substrate. Alternatively, the seed layer 150 may not be formed in a completely continuous manner. The seed layer can be distributed across the substrate surface such that each of the seed layer areas is laterally spaced apart from the other seed layer areas across the substrate surface and do not completely cover the substrate surface. For example, the thickness of the seed layer 150 can be a monolayer or less, such as between 2.0 and 4.0 Å, and the separation between the layer sections may be the result of forming such a thin seed layer (i.e., such a thin layer may not form a continuous layer).

The reflective layer 154 is formed on the seed layer 150. The IR reflective layer can be a metallic, reflective film, such as silver, gold, or copper. In general, the IR reflective film comprises a good electrical conductor, blocking the passage of thermal energy. In some embodiments, the reflective layer 154 is made of silver and has a thickness of, for example, 100 Å. Because the reflective layer 154 is formed on the seed layer 150, for example, due to the (002) crystallographic orientation of the seed layer 150, growth of the silver reflective layer 154 in a (111) crystalline orientation is promoted, which offers low sheet resistance, leading to low panel emissivity.

Because of the promoted (111) texturing orientation of the reflective layer 154 caused by the seed layer 150, the conductivity and emissivity of the reflective layer 154 is improved. As a result, a thinner reflective layer 154 may be formed that still provides sufficient reflective properties and visible light transmission. Additionally, the reduced thickness of the reflective layer 154 allows for less material to be used in each panel that is manufactured, thus improving manufacturing throughput and efficiency, increasing the usable life of the target (e.g., silver) used to form the reflective layer 154, and reducing overall manufacturing costs.

Further, the seed layer 150 can provide a barrier between the metal oxide layer 140 and the reflective layer 154 to reduce the likelihood of any reaction of the material of the reflective layer 154 and the oxygen in the lower metal oxide layer 140, especially during subsequent heating processes. As a result, the resistivity of the reflective layer 154 may be reduced, thus increasing performance of the reflective layer 154 by lowering the emissivity.

Formed on the reflective layer 154 is a barrier layer 156, which can protect the reflective layer 154 from being oxidized. For example, the barrier can be a diffusion barrier, stopping oxygen from diffusing into the silver layer from the upper oxide layer 160. The barrier layer 156 can comprise titanium, nickel or a combination of nickel and titanium.

Formed on the barrier layer 156 is an upper oxide layer, which can function as an antireflective film stack, including a single layer or multiple layers for different functional purposes. The antireflective layer 160 serves to reduce the reflection of visible light, selected based on transmittance, index of refraction, adherence, chemical durability, and thermal stability. In some embodiments, the antireflective layer 160 comprises tin oxide, offering high thermal stability properties. The antireflective layer 160 can also include titanium dioxide, silicon nitride, silicon dioxide, silicon oxynitride, niobium oxide, SiZrN, tin oxide, zinc oxide, or any other suitable dielectric material.

The optical filler layer 170 can be used to provide a proper thickness to the low-e stack, for example, to provide an antireflective property. The optical filler layer preferably has high visible light transmittance. In some embodiments, the optical filler layer 170 is made of tin oxide and has a thickness of, for example, 100 Å. The optical filler layer may be used to tune the optical properties of the low-e panel 105. For example, the thickness and refractive index of the optical filler layer may be used to increase the layer thickness to a multiple of the incoming light wavelengths, effectively reducing the light reflectance and improving the light transmittance.

An upper protective layer 180 can be used for protecting the total film stack, for example, to protect the panel from physical or chemical abrasion. The upper protective layer 180 can be an exterior protective layer, such as silicon nitride, silicon oxynitride, titanium oxide, tin oxide, zinc oxide, niobium oxide, or SiZrN.

In some embodiments, adhesion layers can be used to provide adhesion between layers. The adhesion layers can be made of a metal alloy, such as nickel-titanium, and have a thickness of, for example, 30 Å.

Depending on the materials used, some of the layers of the low-e stack 190 may have some elements in common. An example of such a stack may use a zinc-based material in the oxide dielectric layers 140 and 160. As a result, a relatively low number of different targets can be used for the formation of the low-e stack 190.

In some embodiments, the coating can comprise a double or triple layer stack, having multiple IR reflective layers. In some embodiments, the layers can be formed using a plasma enhanced, or reactive sputtering, in which a carrier gas (e.g., argon) is used to eject ions from a target, which then pass through a mixture of the carrier gas and a reactive gas (e.g., oxygen), or plasma, before being deposited.

In some embodiments, the present invention recognizes an effect of the deposition process of the layers deposited on the silver conductive layer on the quality of the silver conductive layer. Since the silver conductive layer is desirably thin, for example, less than 20 nm, to provide high visible light transmission, the quality of the silver conductive layer can be affected by the deposition of the subsequently deposited layer, such as the barrier layer or the antireflective layer.

For example, high ion energy on the silver conductive layer can degrade the quality of the silver conductive layer, resulting in lower film resistivity and subsequently higher emissivity. Similarly, high ion density or longer exposure time to ion energy can also affect the quality of the silver conductive layer.

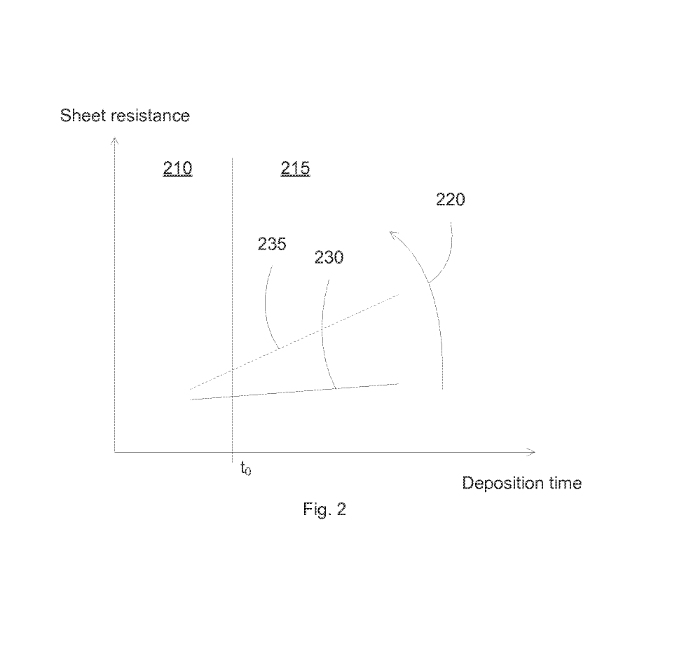

FIG. 2 illustrates an example of the effect of the deposition conditions of a barrier layer on a silver layer according to some embodiments of the present invention. A barrier layer, such as a Ti layer, is sputtered deposited on a silver layer, and the sheet resistance of the silver layer is shown as a function of the deposition time and ion energy/ion density of the Ti layer.

For longer deposition time, the sheet resistance of the silver layer increases, indicating a degradation of the silver layer, for example, by the reaction of the sputtered ions with the silver layer. Low deposition time can reduce the silver layer degradation, however, a minimum deposition time, e.g., to achieve a minimum Ti barrier thickness, might be required to adequately protect the silver layer, for example, from oxygen diffusion. Thus, in some embodiments, the deposition time can be longer or equal to a critical time t₀. In regime 210, the deposition time is less than t₀, the barrier layer might not be continuous, and the sheet resistance of the silver layer can be severely degraded, for example, by the oxidation of the silver layer. Thus the operating window for the barrier deposition can be in regime 215. In some embodiments, deposition at time t₀ is optimum, since thinner barrier layer can contribute the high visible light transmission. However, due to process variations, minimum change in sheet resistance with respect to deposition time can enlarge the process window, potentially improving the yield of the products.

In addition to the time effect, higher ion energy, high ion density, or high ratio of ion to neutral species, as indicated by direction 220, can also increase the degradation, e.g., causing higher sheet resistance, of the silver layer. For example, using lower ion energy 230, such as a long throw deposition process, the sheet resistance of the silver layer can be lower than by using higher ion energy 235, such as a normal (shorter) throw deposition process. As shown, the effect of the ion energy can be seen, in addition to the effect of the deposition time.

In some embodiments, the present invention discloses a sputter deposition having low ion energy, low ion density, or low ion to neutral ratio, which can be applied for a barrier layer or an oxide layer deposited on a conductive layer. For example, the barrier layer can protect the infrared reflective layer from being oxidized. The oxide layer can function as an antireflective layer. The conditions, e.g., low ion energy, low ion density, or low ion to neutral ratio, of the barrier layer deposition process can reduce reaction for the conductive underlayer, preventing resistivity and emissivity degradation. The conditions of the oxide layer deposition process can reduce oxidation of the conductive underlayer, preventing resistivity and emissivity degradation.

In some embodiments, the present invention discloses a sputter deposition process, and coated articles fabricated from the process, including reducing the ions, e.g., ion energy, ion density or ion to neutral ratio, in the reactive species during the sputter deposition, for example, to achieve higher quality coated layers and coated panels.

In some embodiments, the ion control can be achieved by increasing the distance between the sputter target and the substrate, which can decrease the electric field and increase the sputtering area on the substrate for a same number of reactive ions. For example, by increasing the distance from 23 cm to 30 cm, a sheet resistance reduction of 10% of the conductive layer can be obtained, together with a reduction of 1% in emissivity.

In some embodiments, the coated layers can be formed in a sputter deposition chamber that will perform the sputter deposition. The sputter deposition chamber can be designed to reduce or eliminate potential damage to the thin infrared reflective layer, such as limiting the ion density or ion energy of the sputtered particles. For example, the sputter deposition chamber can include a long throw sputter deposition system, which has a longer distance between the target and the substrate than a conventional sputter deposition. In a conventional sputter deposition system, the distance between the target and the substrate is optimized for deposition rate and deposition uniformity. In contrast, a long throw sputter deposition has a longer distance, and thus a much lower deposition rate. In general, a long throw sputter deposition system has a distance of the same order of magnitude as the target size. For example, to deposit on a 300 mm substrate, a target size of 450 mm can be used for preventing edge effects. A long throw deposition system thus can have a substrate positioned at a distance of about 450 mm from the target. A typical long throw sputter deposition can be found in U.S. Patent Application Number 2003/0038023, which is incorporated herein by reference for all purposes.

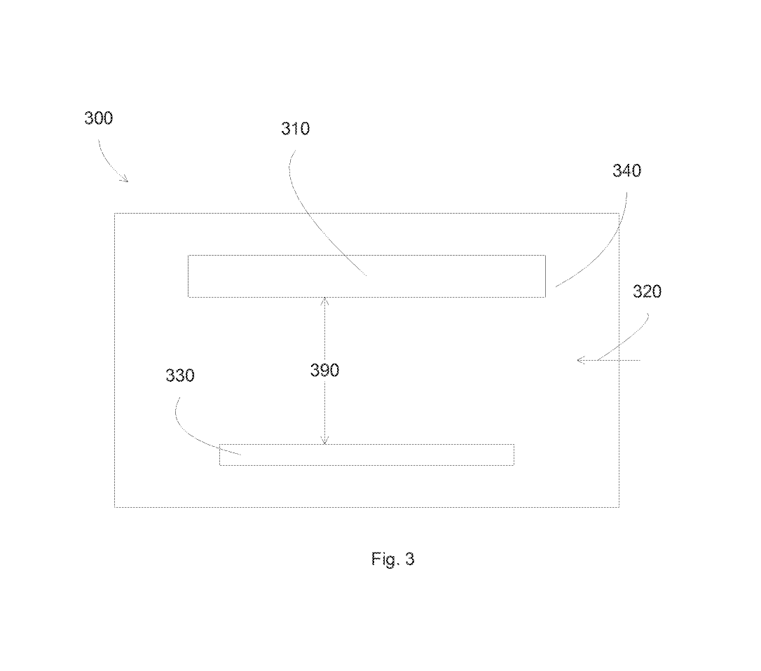

FIG. 3 illustrates a normal throw physical vapor deposition (PVD) system according to some embodiments of the present invention. The PVD system 300 includes a housing that defines, or encloses, a processing chamber 340, a substrate 330, a target assembly 310, and reactive species delivered from an outside source 320. During deposition, the target is bombarded with argon ions, which releases sputtered particles toward the substrate 330.

The materials used in the target 310 may, for example, include tin, zinc, magnesium, aluminum, lanthanum, yttrium, titanium, antimony, strontium, bismuth, silicon, silver, nickel, chromium, copper, gold, or any combination thereof (i.e., a single target may be made of an alloy of several metals). Additionally, the materials used in the targets may include oxygen, nitrogen, or a combination of oxygen and nitrogen in order to form the oxides, nitrides, and oxynitrides of the metals described above. Additionally, although only one target assembly 310 is shown, additional target assemblies may be used. As such, different combinations of targets may be used to form, for example, the dielectric layers described above. For example, in some embodiments in which the dielectric material is zinc-tin-titanium oxide, the zinc, the tin, and the titanium may be provided by separate zinc, tin, and titanium targets, or they may be provided by a single zinc-tin-titanium alloy target. For example, the target assembly 310 can comprise a silver target, and together with argon ions to sputter deposit a silver layer on substrate 330. The target assembly 310 can include a metal or metal alloy target, such as tin, zinc, or tin-zinc alloy, and together with reactive species of oxygen to sputter deposit a metal or metal alloy oxide layer.

In a typical deposition system, the distance 390 between the target 310 and the substrate 330 is generally designed for optimizing the deposition rate and deposition uniformity. Thus a typically distance 390 can be about between 30 to 50 mm, or less than about 230 mm.

The sputter deposition system 300 can include other components, such as a substrate support for supporting the substrate. The substrate support can include a vacuum chuck, electrostatic chuck, or other known mechanisms. The substrate support can be capable of rotating around an axis thereof that is perpendicular to the surface of the substrate. In addition, the substrate support may move in a vertical direction or in a planar direction. It should be appreciated that the rotation and movement in the vertical direction or planar direction may be achieved through known drive mechanisms which include magnetic drives, linear drives, worm screws, lead screws, a differentially pumped rotary feed through drive, etc.

In some embodiments, the substrate support includes an electrode which is connected to a power supply, for example, to provide a RF or DC bias to the substrate, or to provide a plasma environment in the process housing 340. The target assembly 310 can include an electrode which is connected to a power supply to generate a plasma in the process housing. The target assembly 310 is preferably oriented towards the substrate 330.

The sputter deposition system 300 can also include a power supply coupled to the target electrode. The power supply provides power to the electrodes, causing material to be, at least in some embodiments, sputtered from the target. During sputtering, inert gases, such as argon or krypton, may be introduced into the processing chamber 340 through the gas inlet 320. In embodiments in which reactive sputtering is used, reactive gases may also be introduced, such as oxygen and/or nitrogen, which interact with particles ejected from the targets to form oxides, nitrides, and/or oxynitrides on the substrate.

The sputter deposition system 300 can also include a control system (not shown) having, for example, a processor and a memory, which is in operable communication with the other components and configured to control the operation thereof in order to perform the methods described herein.

In some embodiments, the present invention discloses methods and apparatuses for making layers above the thin low resistive silver layer, including controlling the ion energy on the substrate, so that the deposition is performed at a low ion energy, which can reduce damage to the silver underlayer.

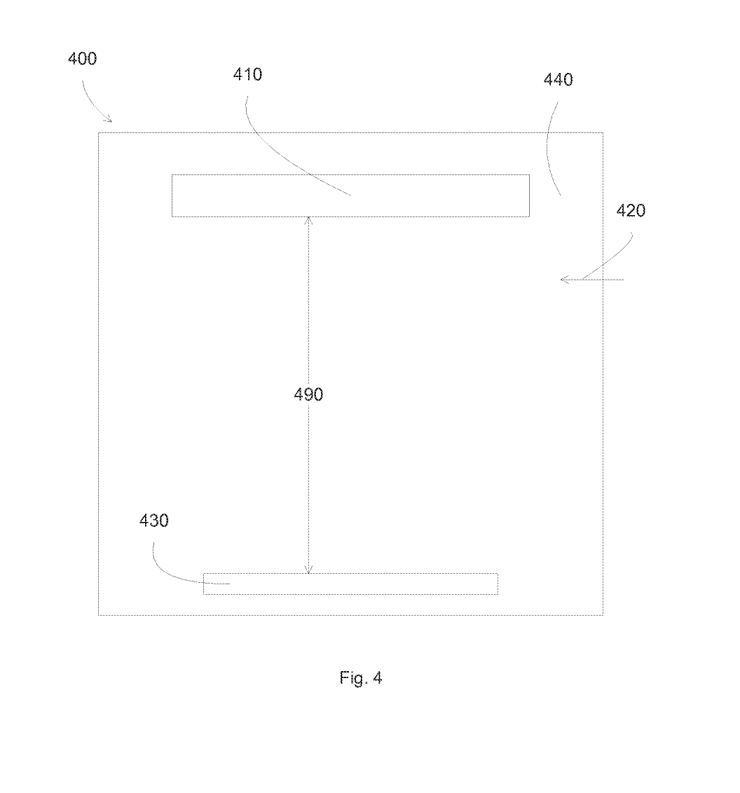

FIG. 4 illustrates a long throw physical vapor deposition (PVD) system according to some embodiments of the present invention. The long throw sputter deposition can include similar components as the normal throw sputter system, except for a longer distance between the target and the substrate. A sputter deposition system 400 can include a target assembly 410 disposed in a housing 440, containing reactive species delivered from an outside source 420. The target assembly 410 generally includes one or more materials that are to be used to deposit a layer of material on the upper surface of the substrate 430. In a long throw deposition system, the distance 490 between the target 410 and the substrate 430 is generally designed for reducing the ion energy effect, e.g., to reduce the damage on the silver underlayer during the deposition process. Thus a typically distance 490 can be between about 230 to 500 mm.

In some embodiments, the ion energy can be reduced by reducing the bias to the substrate, thus reducing the acceleration of the ions toward the substrate. An inductively coupled plasma can be used to generate a plasma, sputtering the ions from the targets, while reducing the acceleration toward the substrate.

In some embodiments, the ion control can be achieved by reducing the ion density in the sputter chamber, including reducing the ratio of ion species to neutral species. For example, a screen shield can be disposed between the sputter target and the substrate, blocking more ion species than neutral species, thus effectively increasing the ion to neutral ratio. The screen shield can have one or more openings, allowing the neutral species to reach the substrate. The screen shield can be floated, e.g., not connecting to any ground or power source. The screen shield can be grounded, e.g., having a zero potential, or can be connected to a voltage source to have a positive or negative potential.

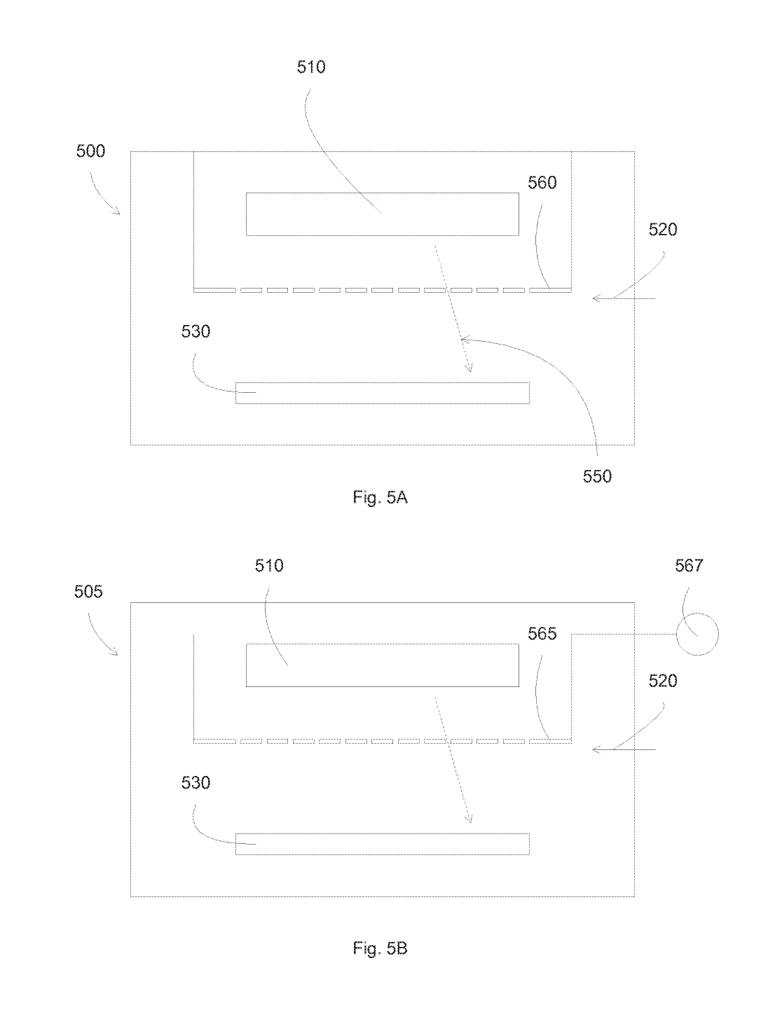

FIGS. 5A-5B illustrate deposition systems having an ion control system according to some embodiments of the present invention. In FIG. 5A, a shield can be used to remove a portion of the ion species, reducing the ion density and/or the ion to neutral ratio. A sputter deposition system 500 can include a target assembly 510 disposed in a housing, containing reactive species delivered from an outside source 520. The target assembly 510 includes a target to be used to deposit a layer of material on the surface of a substrate 530.

The sputter deposition system 500 can further include a shield 560 disposed between the target 510 and the substrate 530. The shield can be float, ground, or biased with a potential. The neutral particles can pass through the shield in a direction 550, while the ion particles can be blocked by the shield 560. The reduction of the ions species can allow less damage to the underlayer.

In some embodiments, the shield 560 can have multiple apertures through which a portion of the ion species can pass through. The apertures can be used to limit the ions from reaching the substrate 330. For example, the generated plasma will dislodge particles from the target to be deposited on the exposed surface of the substrate. The shield 560 having the apertures can imposes limitations on the ion to neutral species between the target and the substrate, potentially resulting in less damage to the underlayer.

In some embodiments, the shield 560 can be floated. In some embodiments, the shield 560 can be electrical connected to the ground, thus attracting ions to the shield while posing no effect on the neutral species. Thus a grounded shield can reduce the ion density, or increase the ion to neutral ratio of the particles reaching the substrate.

In some embodiments, the shield 560 can be disposed in a close proximity to the target, for example, less than 5 cm or less than 10 cm. In some embodiments, the shield 560 can further include a sleeve portion covering the sidewalls of the process housing.

In some embodiments, the sputter deposition system can include a shield between the target and the substrate. The shield can have one or more openings with the aspect ratio of the openings optimized for reducing ion effect on the underlayer, such as reducing the degradation of the silver underlayer.

In some embodiments, the present invention discloses a method of forming a thin layer which includes placing a shield between a target and a substrate to impose limitations on the ions reaching the substrate. For example, for a silver layer less than 20 nm, or less than 15 or 12 nm, the ion control can be optimized to achieve a sheet resistance of the silver layer to be less than 7 Ohm/square.

In some embodiments, the screen shield can be biased with a voltage, further repelling or attracting the ion species while not affecting the neutral species. Other configuration can be used, such as lowering the plasma energy in the sputtering process, effectively reducing the ion density. Alternatively, the neutral species can be increased by adding gases with high ionization energy, which remain in neutral form in the plasma sputtering ambient.

In FIG. 5B, the screen shield is biased with a voltage, for example, by connecting to a power supply. The bias voltage is configured to prevent ion species to pass through the screen shield, thus lowering the ion density or ion energy of the sputtered particles. For example, the shield 565 can be connected to a power supply 567. The power supply 567 can be a controllable power supply, allowing varying the potential to increase or decrease the blockage of the ions. For example, for positive ions, a more positive potential at the shield 565 can act to repel the ions, thus allowing more neutral species to pass through the shield. In some embodiments, the power supply 567 can be controlled to minimize the damage to the silver underlayer, for example, by varying the power and polarity to the shield 565.

In some embodiments, the present invention discloses methods and apparatuses for making low emissivity panels, including forming layers on a conductive material (such as silver, gold or copper) with minimum degradation. In some embodiments, the layers formed on the conductive layer can be formed by a sputtering process with ion control, such as lower ion energy, lower ion density or lower ion to neutral ratio.

In some embodiments, the present invention discloses methods and apparatuses for making low emissivity panels which can include a low resistivity thin infrared reflective layer including a conductive material such as silver, gold, or copper. The thin silver layer can be thinner than about 20 nm, such as thinner than about 15 or 12 nm, such as about 7 or 8 nm, and can have resistivity less than about 5 μΩ-cm. The deposition of subsequent layer on the silver layer can be performed under the control of the ion species, such as controlling the ion energy, ion density, and ion to neutral ratio.

In some embodiments, the ions of the sputter deposition process controlled so that for a thin conductive layer thinner than 20 nm, such as 10, 8 or 7, the sheet resistance can be lower than 7 Ohm/square, the resistivity can be lower than 5 μΩ-cm, or the emissivity can be lower than 9%.

In some embodiments, the present invention discloses methods for making low emissivity panels in large area coaters. A transport mechanism can be provided to move a substrate under one or more sputter targets, to deposit a conductive layer underlayer before depositing a barrier layer, an antireflective layer, together with other layers such as a surface protection layer. A screen shield can be positioned between the targets and the substrate to control the ions, such as reduce the ion density and the ion energy of the sputter particles, helping to improve the conductivity of the conductive underlayer during the deposition of the top layers, such as the barrier layer or the antireflective layer.

In some embodiments, the present invention discloses an in-line deposition system, including a transport mechanism for moving substrates between deposition stations. In some deposition stations, a long distance between the target and the substrate can be provided to control the ions reaching the substrates. For example, the distance between the target and the substrate of the deposition station for depositing a conductive layer (e.g., silver layer) can be less than the distance in a subsequent deposition station. In some deposition stations, a shield can be provided to control the ions reaching the substrates.

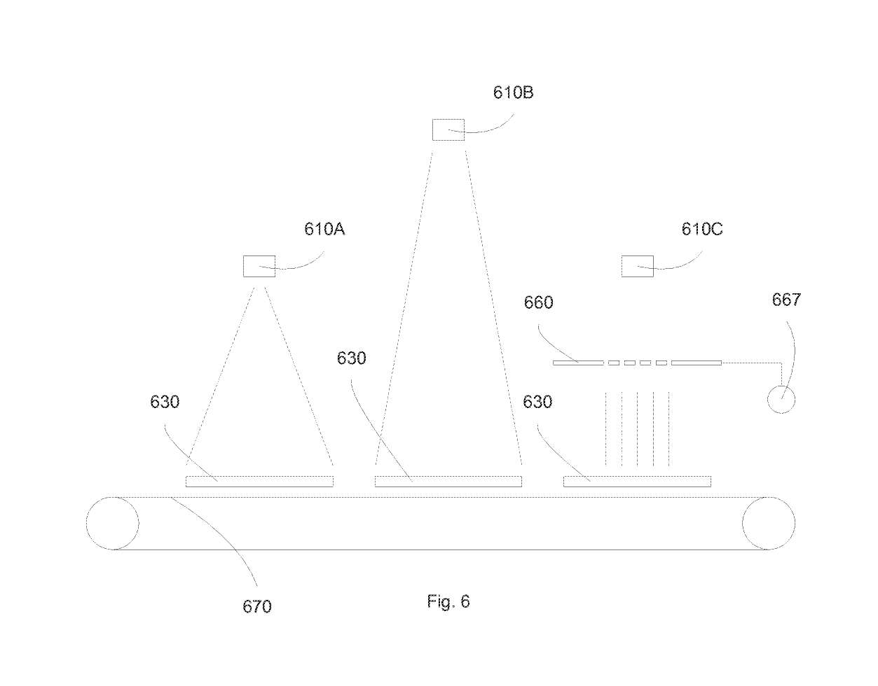

FIG. 6 illustrates an exemplary in-line deposition system according to some embodiments of the present invention. A transport mechanism 670, such as a conveyor belt or a plurality of rollers, can transfer substrate 630 between different sputter deposition stations. For example, the substrate can be positioned at station #1, having a target assembly 610A, then transferred to station #2, having target assembly 6108 disposed at a longer distance to the substrate, and then transferred to station #3, having target assembly 610C and shield 660. The station #1 having target 610A can be a normal throw sputtering station, sputtering particles to optimize the quality of the deposited film. The stations #2 and #3 having target assemblies 610B and 610C can have ion control mechanisms, to control the ions of the sputter process to minimizing damage to the deposited layer deposited by station #1.

In some embodiments, the long throw station #2 can have a longer distance between the target 610B and the substrate, as compared to that of station #1. For example, a short distance station can be used to deposit a silver layer, in which the process conditions are optimized to achieve an optimum silver layer. A longer distance deposition station can be used to deposit a substrate layer, such as a barrier. The long throw station can reduce the ion energy, such as the ion bombardment to the silver underlayer, minimizing potential damages to the silver layer.

In some embodiments, station #3 can have a screen shield 660 to control the ions that can reach the substrate. The shield 660 can be coupled to a power supply to vary the amount of the ions that can pass through the shield 660. The shield can control the ions, such as ion energy, ion density and ion to neutral ratio, which can reduce the degradation on the silver layer.

In some embodiments, the screen shield can include multiple openings, wherein the openings are staggered so that a deposited layer is continuous along a direction not parallel to the moving direction of the substrate. The sizes of the openings are configured to lower the ion density or ion energy of the sputtered particles to achieve a desired panel quality. The staggered collimator is configured to deposit a band of material on the substrate through the openings, permitting in-line large area coating while the substrate is moving forward.

Other configurations of sputter stations can be used, such as all long throw sputtering stations, or all shielded sputtering stations. In addition, other stations can be included, such as input and output stations, or anneal stations.

In some embodiments, the present invention discloses methods for sputtering layers on a conductive layer to minimize potential damages on the conductive layer. The methods can include control the ions from the sputter deposition process, such as controlling the ion energy, the ion density and the ion to neutral ratio, so that the deposition of the sputter layer does not affect, or have minimum effect, on the conductive underlayer.

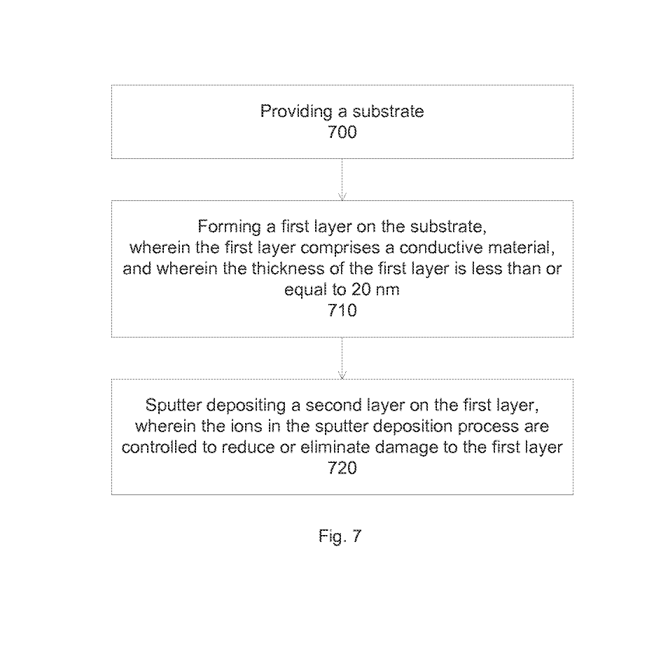

FIG. 7 illustrates a flow chart for sputtering coated layers according to some embodiments of the present invention. After forming a conductive layer on a substrate, such as a silver layer, other layers can be sputtered deposited on the conductive layer with ion conditions that do not affect the conductive layer, only affecting less than about 5% (or 10%) of some properties of the conductive layer, or to achieve a conductive layer having sheet resistance of less than about 7 Ohm/square or having resistivity less than about 5 μΩ-cm for a conductive layer thickness of less than about 20 nm or less than 10 nm.

In operation 700, a substrate is provided. The substrate can be a transparent substrate, such as a glass substrate or a polymer substrate. Other substrates can also be used. In operation 710, a first layer is formed on the substrate. The first layer can include a conductive material or a metallic material such as silver. The thickness of the first layer can be less than or equal to about 20 nm, or can be less than or equal to about 10 nm.

In operation 720, a second layer is sputter deposited on the first layer. The ions in the deposition can be controlled to reduce or eliminate damage to the first layer. In some embodiments, the sheet resistance, the resistivity or the emissivity of the conductive layer are not affected by the sputter deposition process to form the second layer. In some embodiments, the sheet resistance, the resistivity or the emissivity of the conductive layer change less than or equal to about 5%. In some embodiments, the sheet resistance of the conductive layer is maintained at less than or equal to about 7Ω/square. In some embodiments, the resistivity of the conductive layer is maintained at less than or equal to about 5 μΩ-cm. In some embodiments, the emissivity of the conductive layer is maintained at less than or equal to about 9%.

In some embodiments, the ions can be controlled, for example, reducing the ion energy, reducing the ion density, and/or reducing the ion to neutral ratio, by increasing a distance between the sputter target and the substrate. For example, a long throw sputter deposition condition can be used to lower the ion energy reaching the substrate. The ions can be controlled by adding a screen between a sputter target and the substrate. The screen can block more ions than neutral species, thus can lower the ion density or ion to neutral ration. The shield can be grounded, e.g., connecting to a ground terminal. The shield can be connected to a power supply, which can vary the potential of the shield, and can provide more control to the ions within the sputter deposition chamber.

In some embodiments, the second layer can include a barrier layer, an antireflective layer, an optical filler layer, a protective layer, or any combination thereof. In some embodiments, the second layer can include a titanium layer, a zinc oxide layer, an alloy oxide layer, a silicon nitride layer, or any combination thereof.

In some embodiments, an underlayer can be formed under the first layer. In some embodiments, other layers can be formed on the second layer.

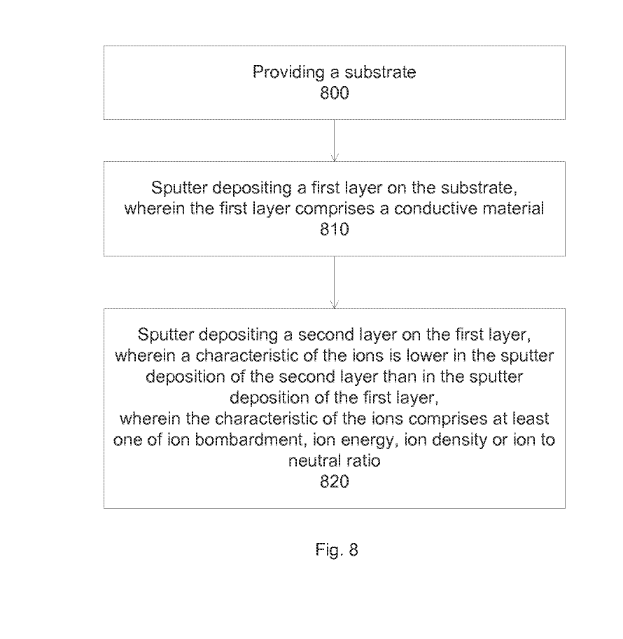

FIG. 8 illustrates a flow chart for sputtering layers according to some embodiments of the present invention. After sputter depositing a conductive layer on a substrate, such as a silver layer, other layers can be sputtered deposited on the conductive layer with a characteristic of the ions that is lower than in the conductive layer process. The ion characteristic can include at least one of ion energy, ion density or ion to neutral ratio. For example, the other layers can be deposited in a sputter deposition chamber that has lower ion energy, ion density or ion to neutral ratio than in the sputter deposition chamber that deposits the conductive layer.

In operation 800, a substrate is provided. The substrate can be a transparent substrate, such as a glass substrate or a polymer substrate. Other substrates can also be used. In operation 810, a first layer is formed on the substrate. The first layer can include a conductive material or a metallic material such as silver.

In operation 820, a second layer is sputter deposited on the first layer. A characteristic of the ions is lower in the sputter deposition of the second layer than in the sputter deposition of the first layer. The characteristic of the ions can include at least one of ion energy, ion density or ion to neutral ratio.

For example, a distance between a target and the substrate in the second deposition chamber is longer than a corresponding distance between a target and the substrate in the first deposition chamber. Thus the ion energy in the second deposition can be lower than that in the first deposition chamber. Alternatively, a bias in the second deposition chamber can be lower than that in the first deposition chamber, resulting in lower ion energy toward the substrate.

A shield can be disposed between a target and the substrate in the second deposition chamber. Thus the ion density or the ion to neutral ratio in the second deposition can be lower than that in the first deposition chamber.

A power supply can be coupled to the shield, further allowing control of the ion density or the ion to neutral ratio.

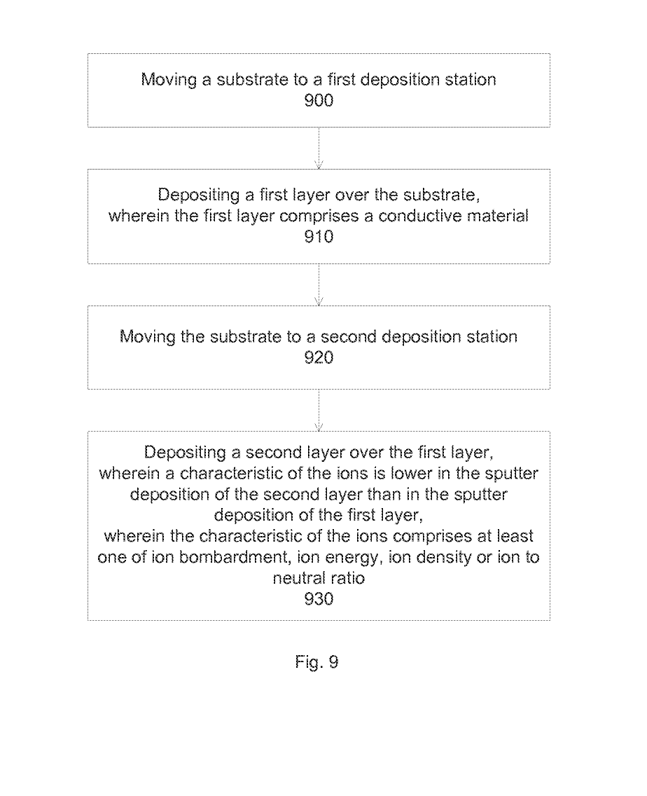

FIG. 9 illustrates another flow chart for sputtering coated layers according to some embodiments of the present invention. A substrate can be transported between deposition chambers for sequentially depositing coated layers. In operation 900, a substrate is transported to a first sputter deposition chamber. In operation 910, a first layer is deposited on the substrate in the first sputter deposition chamber. In operation 920, the substrate is transported to a second sputter deposition chamber. In operation 930, a second layer is deposited on the first layer. A characteristic of the ions is lower in the sputter deposition of the second layer than in the sputter deposition of the first layer. The characteristic of the ions can include at least one of ion energy, ion density or ion to neutral ratio.

In some embodiments, other deposition chambers or layers can be included, such as a protective layer, an oxide layer, a barrier layer, an antireflective oxide, an optical filler layer, an interface layer and an adhesion layer. The additional layers can be sputtered deposited by reduced ion energy, ion density, or ion to neutral ratio to reduce damage to the silver conductive layer.

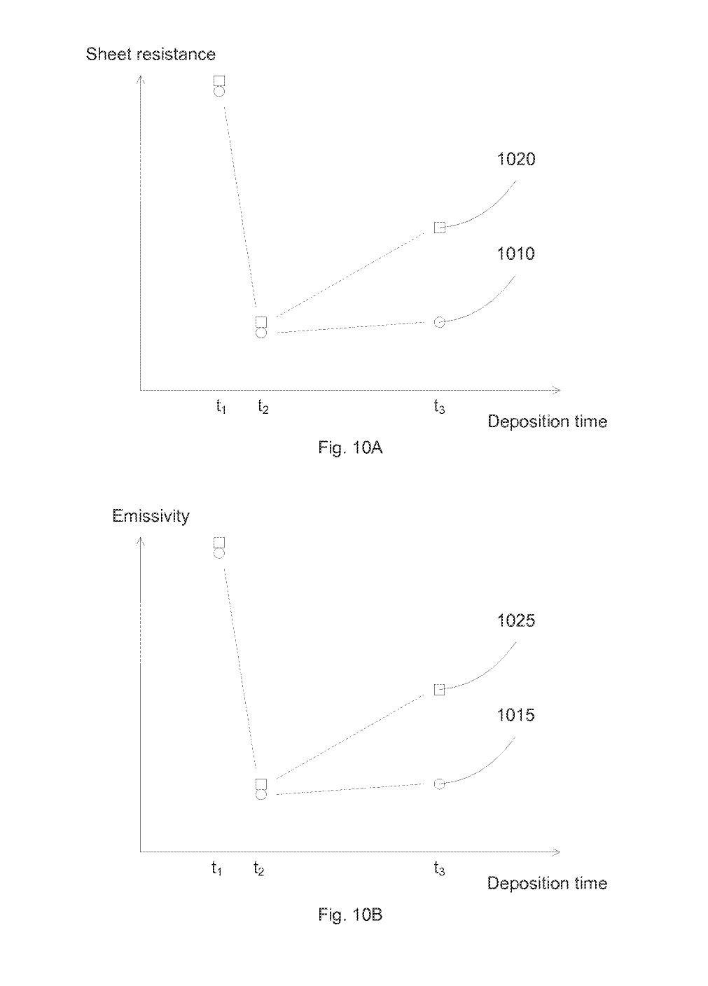

FIGS. 10A-10B illustrate examples of sheet resistance and emissivity data for low emissivity stacks according to some embodiments of the present invention. A silver layer of about 12 nm thick is deposited on a substrate, by sputter deposition. A titanium layer is then deposited on the silver layer. In FIG. 10A, sheet resistance of the composite layer, e.g., the titanium layer on the silver layer, is plotted as a function of the deposition time of the titanium layer. In FIG. 10B, emissivity of the composite layer, e.g., the titanium layer on the silver layer, is plotted, also as a function of the deposition time of the titanium layer. Two process conditions are used, including a normal throw sputter deposition process, having the distance between the target and the substrate of about 230 mm (represented by squares 1020 and 1025), and a long sputter deposition process, having the distance between the target and the substrate of about 300 mm (represented by circles 1010 and 1015).

At low deposition time t₁, the sheet resistance and the emissivity is high, probably due to the incomplete coverage of the titanium layer, which does not provide adequate protection for the silver layer. Thus the silver layer can be partially oxidized, resulting in high sheet resistance. At medium deposition time t₂, the sheet resistance and the emissivity are low, with small differences between the normal throw and long throw deposition conditions. At long deposition time t₃, the sheet resistance and the emissivity are slightly higher, with much larger differences between the normal throw and long throw deposition conditions.

The illustration shows that the low ion energy, represented by the long throw deposition of 300 mm, provides less degradation to the silver layer. At medium deposition time t₂, the difference can be small, but at longer deposition time t₃, the difference can be large. The long throw deposition conditions, indicating a low ion energy, low ion density, or low ion to neutral ratio, can have significant effect in enlarging the process window, allowing a larger variation in the deposition time of the titanium layer without significant change in the quality of the silver layer.

Although the foregoing examples have been described in some detail for purposes of clarity of understanding, the invention is not limited to the details provided. There are many alternative ways of implementing the invention. The disclosed examples are illustrative and not restrictive.

What is claimed is:

1. A method for coating a substrate, the method comprising
providing the substrate;
depositing a first layer over the substrate,
wherein the first layer comprises a conductive material,
wherein the thickness of the first layer is less than 20 nm;
depositing a second layer on the first layer,
wherein the depositing is a sputter deposition process,
wherein the sputter deposition process produces ion and neutral species;
wherein the ion to neutral species ratio is altered by passing the ion and neutral species through a shield maintained at a voltage.

2. A method as in claim 1, further comprising
forming an underlayer between the substrate and the first layer.

3. A method as in claim 1 wherein the first layer comprises silver.

4. A method as in claim 1, wherein the thickness of the first layer is less than 10 nm.

5. A method as in claim 1 wherein the second layer comprises titanium or ZnO.

6. A method as in claim 1 wherein ions in the sputter deposition process are controlled to maintain the resistivity of the layers on the substrate to be less than or equal to 5 μΩ-cm.

7. A method as in claim 1 wherein ions in the sputter deposition process are controlled to maintain the emissivity of the layers on the substrate to be less than or equal to 9%.

8. A method as in claim 1, wherein the shield is maintained at a ground potential.

9. A method as in claim 1, wherein the shield is coupled to a power supply.

10. A method as in claim 1, wherein a distance between a target to the substrate in the second deposition process is longer than a distance between a target to the substrate in the first deposition process.

11. A system for coating a substrate, the system comprising
a transport mechanism for transporting a substrate;
a first sputter deposition chamber for sputter depositing a first layer on the substrate, wherein sputter depositing a first layer comprises generating first ion and neutral species in the first sputter deposition chamber;
a second sputter deposition chamber for sputter depositing a second layer on the first layer, wherein sputter depositing a second layer comprises generating second ion and neutral species in the second sputter deposition chamber, wherein the second ion to neutral species ratio is altered by passing the second ion and neutral species through a shield maintained at a voltage;
wherein the transport mechanism transfers the substrate from the first sputter deposition chamber to the second sputter deposition chamber.

12. A system as in claim 11, wherein a distance between a target to the substrate in the second deposition chamber is longer than a distance between a target to the substrate in the first deposition chamber.

13. A system as in claim 11, wherein the shield is maintained at a ground potential.

14. A system as in claim 11, wherein the shield is coupled to a power supply.

15. A system as in claim 11, wherein the first sputter deposition chamber is operable to deposit a silver layer, and wherein the second sputter deposition chamber is operable to deposit a titanium layer or a ZnO layer.

16. A system as in claim 11, further comprising
a third sputter deposition chamber for sputter depositing an underlayer between the substrate and the first layer.

17. A method as in claim 11 wherein the first layer comprises silver and wherein the second layer comprises titanium or ZnO.

18. A method as in claim 11, wherein the thickness of the first layer is less than 10 nm.

19. A system for coating a substrate, the system comprising
a transport mechanism for transporting a substrate;
a first sputter deposition chamber for sputter depositing a first layer on the substrate, wherein sputter depositing a first layer comprises generating first ion and neutral species in the first sputter deposition chamber;
a second sputter deposition chamber for sputter depositing a second layer on the first layer, wherein sputter depositing a second layer comprises generating second ion and neutral species in the second sputter deposition chamber;
wherein the transport mechanism transfers the substrate from the first sputter deposition chamber to the second sputter deposition chamber,
wherein the second ion to neutral species ratio is smaller than the first ion to neutral species ratio.

20. A method as in claim 19, wherein the second deposition process comprises a shield disposed between a target and the substrate, and wherein the shield is coupled to a power supply.
